(19) United States
(12) Patent Application Publication
(10) Pub. No.: US 2005/0109732 A1
(43) Pub. Date: May 26, 2005

(54) Method for manufacturing organic electroluminescent element and apparatus using the method

(75) Inventor: Tatsuya Yoshizawa, Tsurugashima-shi (JP)

Correspondence Address: SUGHRUE MION, PLLC, 2100 PENNSYLVANIA AVENUE, N.W., SUITE 800, WASHINGTON, DC, 20037, US

(73) Assignee: PIONEER CORPORATION

(21) Appl. No.: 10/994,315

(22) Filed: Nov. 23, 2004

(30) Foreign Application Priority Data
Nov. 25, 2003 (JP) 2003-393685

(51) Int. Cl. B44C 1/22; C03C 15/00; C03C 25/68; C23F 1/00

(52) U.S. Cl. 216/41; 427/66; 118/719

(57) ABSTRACT

A method for manufacturing an organic electroluminescent element whose emission property is stable for a long time and a manufacturing apparatus using the method. The organic EL element manufacturing method includes an anode layer formation process for forming an anode layer on a substrate, an organic functional layer formation process for forming an organic functional layer having at least a light emission layer on the anode layer, a cathode layer formation process for forming a cathode layer on the organic functional layer, and a sealing process for sealing an organic electroluminescence element formed of the anode layer, the organic functional layer, and the cathode layer with a sealing member. The anode layer formation process includes an anode film formation step of forming the anode layer on the substrate, a step of disposing a resist on the anode layer, an etching step of performing etching processing on the anode layer by using the resist as a mask, a resist removal step of removing the resist by dry ashing processing after the etching step, and a surface treatment step of performing a surface treatment on the anode layer after the resist removal step. The anode layer is not exposed to the air after the resist removal step.

### BACKGROUND OF THE INVENTION

1. Field of the Invention

The present invention relates to an organic electroluminescent element manufacturing method and an apparatus using the method.

2. Description of the Related Art

An organic electroluminescent element (hereinafter referred to as an organic EL element) includes an anode, a cathode, and an organic functional layer made of an organic compound material and sandwiched between the anode and the cathode. The organic functional layer includes a light emission layer and has an electroluminescent property. The organic functional layer is either a single layer structure consisting of a light emission layer or a multi-layer stack such as a three layer structure including a hole transport layer, a light emission layer, and an electron transport layer.

By applying a voltage across the anode and the cathode of the organic EL element, holes are injected from the anode to the organic functional layer while electrons are injected from the cathode to the organic functional layer. The holes are recombined with the electrons inside the organic functional layer to give luminescence light emission.

In a manufacture of the above-described organic EL element, the anode is firstly formed on a substrate. The anode is formed by forming on a substrate an ITO film made of an indium tin oxide by using a film formation method such as sputtering and then subjecting the ITO film to etching processing under a reduced pressure using a metal mask having a predetermined pattern as a mask. Thus, the patterned anode is formed. Then, a surface treatment such as plasma processing or the like is performed on the anode, and the organic functional layer is formed on the anode after the surface treatment by using a film formation method such as vapor deposition. A cathode made of a low resistance material such as aluminum or the like is formed on the organic functional layer by using a film formation method such as vapor deposition. The organic EL element is thus obtained (see Japanese Patent kokai No. 10-302965).

Though it is possible to form an organic EL element having a satisfactory light emission property according to the above method, the method has a problem that it is difficult to process the metal mask used for patterning the anode in minute details. More specifically, it is difficult to process a masking portion having a minute width, and that the masking portion with the minute width tends to be deteriorated in strength, so that a metal mask having a large area is subject to distortion. Therefore, it is difficult to process the organic EL element in minute details in the manufacture of the organic EL element, particularly in a manufacture of an organic EL display panel having a substrate provided with a plurality of the organic EL elements.

In turn, the method of forming the organic EL element by using a resist as the mask has a problem that satisfactory luminosity is not obtained due to a reduction in efficiency of the hole injection from the anode to the organic functional layer, which is caused by factors such as contamination by a resist residue remaining on a surface of the anode after the patterning, deposition of an organic contaminant in the air on the anode surface due to processing in the air, and absorption of moisture in the air.

The above problem is included in problems that this invention is to solve.

### SUMMARY OF THE INVENTION

According to one aspect of this invention, an organic electroluminescent element manufacturing method comprises: an anode layer formation process including an anode film formation step of forming an anode layer on a substrate, a step of disposing a resist on the anode layer, an etching step of performing etching processing on the anode layer by using the resist as a mask, a resist removal step of removing the resist by dry ashing processing after the etching step, and a surface treatment step of performing a surface treatment on the anode layer after the resist removal step; an organic functional layer formation process for forming an organic functional layer having at least a light emission layer on the anode layer; a cathode layer formation process for forming a cathode layer on the organic functional layer; and a sealing process for sealing an organic electroluminescent element formed of the anode layer, the organic functional layer, and the cathode layer with a sealing member, wherein the anode layer is not exposed to the air after the resist removal step.

According to another aspect of this invention, an organic EL element manufacturing apparatus comprises: a processing unit including a load chamber for introducing a structural body having a substrate, an anode layer provided on the substrate, and a resist disposed on the anode layer, an ashing chamber for removing the resist by dry ashing, a surface treatment chamber for performing a surface treatment on a surface of the anode layer from which the resist has been removed, an organic functional layer formation chamber for forming an organic functional layer on the anode layer on which the surface treatment has been performed, a cathode layer formation chamber for forming a cathode layer on the organic functional layer, and a sealing chamber for sealing an organic electroluminescent element formed of the anode layer, the organic functional layer, and the cathode layer with a sealing member; and a conveyance chamber which is provided with a connection to the processing unit and a unit for conveying the substrate, wherein the conveyance chamber includes a decompression unit.

### BRIEF DESCRIPTION OF THE DRAWINGS

FIG. 1 is a sectional view showing manufacturing process steps of an organic EL element.

FIG. 2 is a sectional view showing manufacturing process steps subsequent to FIG. 1.

FIG. 3 is a plan view showing an organic EL element manufacturing apparatus according to this invention.

FIG. 4 is a plan view showing a modification exampled of the organic EL element manufacturing apparatus according to this invention.

### DETAILED DESCRIPTION OF THE INVENTION

One embodiment of the organic EL element manufacturing method of this invention will be described in detail with reference to the accompanying drawings.

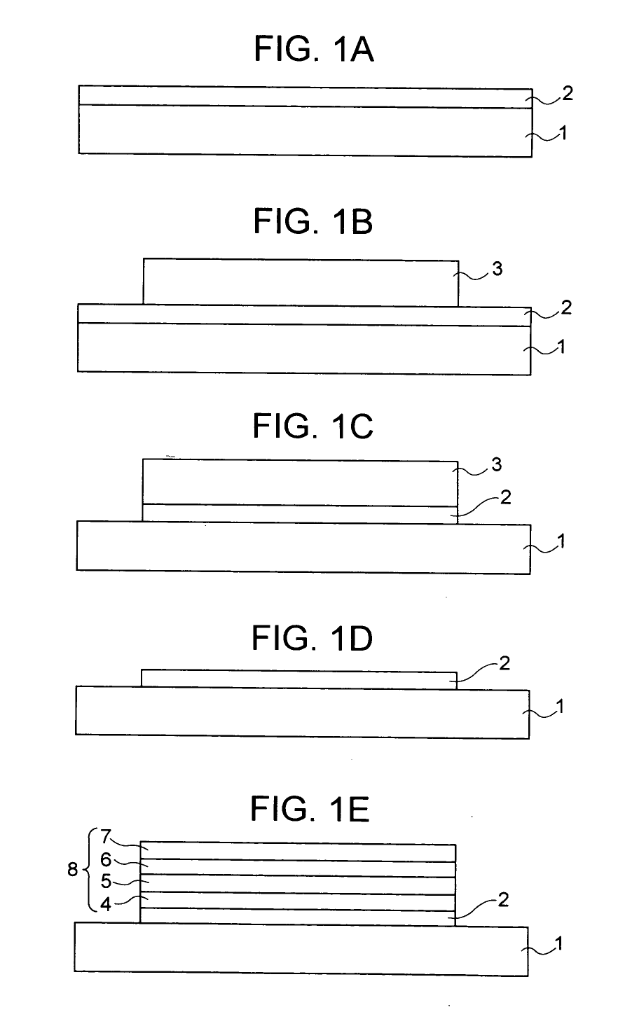

As shown in FIG. 1A, an anode layer 2 is formed on a substrate 1 made of a glass, a resin or the like by using a film formation method such as sputtering. The anode layer 2 is made of an electroconductive substance having a large work function, such as ITO and indium zinc oxide.

After the formation of the anode layer 2, a resist 3 having a predetermined pattern is disposed on the anode layer 2 (FIG. 1B). After that, etching processing is performed using the resist 3 as a mask (FIG. 1C). As the etching processing, wet etching processing or dry etching processing may be employed.

In the wet etching processing, the etching is performed by using a hydrochloric acid solution containing ferric chloride, hydrochloric acid, oxalic acid, and halogen acid such as hydroiodic acid, or nitrohydrochloric acid as an etchant.

The dry etching processing may be plasma etching processing using an etching gas such as CH₄, HCl, HBr, HI, C₂H₅I, Br₂, and I₂. The plasma etching processing is performed by using, for example, a parallel plate type plasma etching apparatus. Reactive ion etching (RIE) processing using a mixture gas of a halogenated hydrogen gas such as a hydrogen iodide gas and an inert gas such as a helium gas may be employed as the dry etching processing.

The resist is removed by placing the substrate after the etching processing in a decompression chamber (not shown) and performing dry ashing processing on the substrate under a reduced pressure. As the dry ashing processing, plasma ashing processing or ozone ashing processing may be employed.

In the plasma ashing processing, a plasma gas is reacted with the resist so that the resist is decomposed and removed. The plasma is generated by applying an RF voltage to an atmospheric gas such as oxygen. The plasma generated when the atmospheric gas is oxygen or a mixture gas containing oxygen is called oxygen plasma, and the resist reacted with the oxygen plasma is decomposed into carbon dioxide, oxygen, moisture, and like gases to be removed.

In the ozone ashing processing, an ozone gas is reacted with the resist to decompose the resist for its removal. The ozone gas is generated by irradiating an oxygenated gas with ultraviolet rays, for example. Oxygen radicals of the reactive gas generated by the decomposition of the ozone gas react with the resist, and the resist is decomposed into carbon dioxide, oxygen, moisture, and like gases to be removed.

The resist is removed by the above-described dry ashing processing to give the patterned anode layer 2 (FIG. 1D). Process steps after the resist removal are performed under a reduced pressure without exposing the anode layer to the air.

After the patterning on the anode layer, a surface treatment is performed on the anode layer. As the surface treatment, at least one of aheat treatment,a UV/ozone treatment, an excimer treatment, and a plasma treatment is performed on the anode layer.

In the heat treatment, a surface of the anode layer is heated with a temperature of 100° C. or more. Usable heating methods are a resistance heating method, an induction heating method, a dielectric heating method, and a microwave heating method, for example. Heat generated by an electroconductive body which conducts a current is used in the resistance heating method, and a heater (hot plate) or the like may be used a heating unit. A temperature rise in a substance, which is caused by an induction current from a coil connected to an alternating power source having a frequency of from a several kilohertz to a several megahertz, is utilized in the induction heating method. A temperature rise in a substance, which is caused by an electric loss (dielectric loss) generated when an electrical insulating substance is placed in an alternating electric field having a frequency of from a several megahertz to a several tens of megahertz (e.g. 13.56 MHz, 27.12 MHz, 40.68 MHz), is utilized in the dielectric heating method. In the microwave heating method, heating of a dielectric body, which is generated by friction due to molecular vibration caused by an electric field of a microwave (from a several hundreds of megahertz to a several hundreds of gigahertz, for example, 2.45 GHz and 28 GHz) penetrated into a dielectric substance, is utilized. By the heating, moisture in the anode (contained moisture) is removed.

It is preferable to employ the induction heating method, the dielectric heating method, and the microwave heating method. The reason for the above is that the resistance heating method is an indirect heating method wherein the heat generated by supplying a current to the electroconductive body is transmitted to the substrate by radiation, while the induction heating method, the dielectric heating method, and the microwave heating method is a direct heating method wherein the substrate and/or the anode layer generate(s) heat. That is to say, the direct heating method enables uniform heating in a short time without relying on heat conduction of a material, thereby achieving a better heat efficiency as compared with the indirect heating method.

In the UV/ozone treatment, the substrate is irradiated with ultraviolet rays under the presence of oxygen. As an ultraviolet light source, a mercury lamp and a deuterium lamp each of which is capable of emitting ultraviolet rays having a wavelength of from 150 nm to 350 nm may be used. When the substrate is irradiated with the ultraviolet rays, oxygen is decomposed by the ultraviolet rays to generate ozone and active oxygen, and the ozone and the active oxygen react with contaminants such as resist residue existing on the surface of the anode layer. The contaminants are removed due to the reaction. Modification of the anode layer, such as an oxidation of the anode layer as a result of the reaction of the ozone and the active oxygen with the anode material, is also achieved. An ionization potential of the anode layer is increased due to the oxidation.

In the excimer treatment, the substrate is irradiated with light from an excimer lamp under the presence of oxygen. As the excimer lamp, an excimer lamp utilizing a dielectric barrier discharge may be used, for example. The light emitted from the excimer lamp may preferably have a wavelength of 310 nm or less. As a discharge gas, KrCl, Xe, and XeCl, for example, may be used. Particularly, the excimer lamp using the Xe gas emits light having a luminescence center at 172 nm, and the light contributes to a generation of ozone. Therefore, it is preferable to use the excimer lamp having the Xe gas.

When the substrate is irradiated with the light from the excimer lamp, oxygen is decomposed by the light to generate ozone and active oxygen, and the ozone and the active oxygen react with contaminants such as resist residue existing on the surface of the anode layer. The contaminants are decomposed and removed due to the reaction. Modification of the anode layer, such as an oxidation of the anode layer as a result of the reaction of the ozone and the active oxygen with the anode material, is also achieved. An ionization potential of the anode layer is increased due to the oxidation.

The plasma treatment is an oxygen plasma treatment performed in, for example, the parallel plate type plasma apparatus. In the oxygen plasma treatment, a plasma discharge is caused using as an ambient gas a mixture gas of any one of nitrogen, argon, helium, neon, and xenon and oxygen or a mixture gas obtained by using oxygen containing a halogen gas. More specifically, the mixture gas is introduced into a chamber in which a substrate is placed and a decompressed state is maintained, and then an RF voltage is applied in the chamber. As a result, oxygen plasma is generated to react with contaminants such as organic substances on the anode layer, thereby removing the contaminants. Also, the oxygen plasma reacts with the anode layer to modify the anode layer.

The surface treatment to be performed on the anode layer may include a plurality of surface treatments such as the heat treatment and the plasma treatment, the UV/ozone treatment and the plasma treatment, or the excimer treatment and the plasma treatment. Particularly, it is preferable to combine a chemical cleaning method such as the heat treatment, the UV/ozone treatment, and the excimer treatment with the plasma treatment which is a physical cleaning method. With the above combination of methods, substances which are chemically decomposed are removed by way of the chemical cleaning method and substances which are not removed chemically are removed by way of the physical cleaning method, thereby more efficiently removing the contaminants from the surface of the anode layer.

As described above, the contaminants such as the resist residue on the anode layer are removed by subjecting the surface of the anode layer to the surface treatment. More specifically, the contaminants which have not been removed by the dry ashing processing are completely removed by the heat treatment, the UV/ozone treatment, the excimer treatment, and the plasma treatment. Further, since the treatments are performed successively under the reduced pressure after the dry ashing processing, the anode layer surface is not exposed to the air, so that the anode layer surface is prevented from being contaminated by the air.

As shown in FIG. 1E, on the anode layer 2 which has been subjected to the surface treatment, a hole injection layer 4, a hole transport layer 5, alight emission layer 6, and an electron injection transport layer 7 are formed in this order using a film formation method such as vapor deposition to form an organic functional layer 8.

Examples of a material to be used for the hole injection layer 4 are a phthalocyanine complex such as copper phthalocyanine; an aromatic amine derivative such as 4,4′,4″-tris(3-methylphenyl phenylamino)triphenylamine or the like. A hydrazone derivative, a carbazole derivative, a triazole derivative, an imidazole derivative, an oxadiazole derivative having an amino group, a polythiophene or the like may also be used as the material for the hole injection layer 4.

Examples of a material to be used for the hole transport layer 5 are an aromatic amine derivative such as N,N′-diphenyl-N,N′-di(3-methylphenyl)4,4′-diaminobiphenyl (TPD), NPB (4,4′-bis[N-(1-naphthyl)-N-phenylamino]biphenyl) or the like.

Examples of a material to be used for a light emission layer 6 are a metal complex dye such as (8-quinolinol)aluminum complex (Alq₃); an organic dye which emits fluorescence, such as a coumarin compound or the like.

Examples of a material to be used for the electron injection transport layer 7 are an oxadiazole derivative such as 2-(4-biphenyl)-5-(4-tert-butylphenyl)-1,3,4-oxadiazole, 2,5-bis(1-naphthyl)-1,3,4-oxadiazole or the like. A perylene derivative, a pyridine derivative, a pyrimidine derivative, a quinoline derivative, a quinoxalin derivative, a diphenylquinone derivative, a nitro-substituted fluorene derivative, lithium fluoride, lithium oxide, or a lithium complex may also be used as the material for the electron injection transport layer 7.

The organic functional layer is not limited to the above-described four layer structure. For instance, the organic functional layer may be a single layer structure consisting of a light emission layer, a two-layer structure consisting of a hole transport layer and a light emission layer, or a multi-layer stack wherein an electron or hole injection layer, an electron or hole transport layer, a carrier block layer or the like are inserted between appropriate layers of the two layer structure.

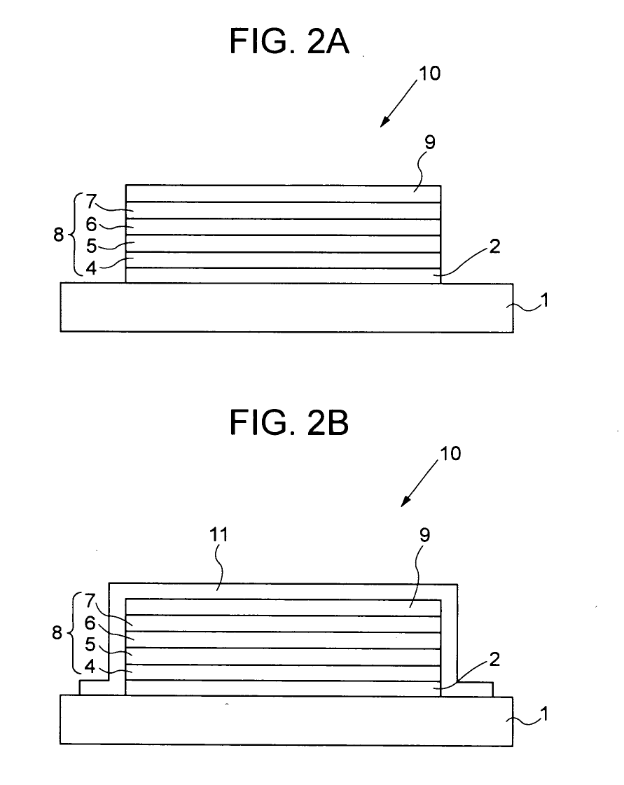

After the formation of the organic functional layer 8, a cathode layer 9 made of an electroconductive substance having a small function is formed (FIG. 2A). Examples of a material to be used for the cathode layer are an alkali earth metal such as magnesium; an alkali metal such as lithium; aluminum; indium; silver; an alloy thereof or the like. A stack on which the cathode layer 9 is formed serves as an organic EL element 10.

As shown in FIG. 2B, the organic EL element 10 is covered with a sealing layer 11 having a property which prevents passage of gases such as moisture, i.e. a gas barrier property, to be sealed. The sealing layer 11 is formed by a film formation method such as plasma CVD. The sealing layer 11 may be made of an inorganic material such as nitride, oxide, and nitride oxide. For instance, silicon nitride, silicon oxide, or silicon nitride oxide may be used as the material for the sealing layer. In addition, a sealing can may be used in place of the sealing layer 11.

As described above, since it is possible to form the pattern of the anode layer by using the resist, it is possible to process the anode layer in minute details as compared with the etching using the metal mask. Therefore, it is possible to obtain a minute organic EL element.

Also, it is possible to prevent the contamination of the anode layer by the organic substances and moisture from the air by performing the process steps after the resist removal under a reduced pressure, and that it is possible to remove the contaminants such as the resist residue from the surface of the anode layer by performing the surface treatment on the anode layer after the resist removal. In other words, it is possible to efficiently remove the contaminants deposited on the anode layer surface before the formation of the organic functional layer. As a result of cleaning the surface of the anode layer, the hole injection efficiency from the anode layer to the organic functional layer is increased to give an organic EL element capable of achieving high luminosity with a low voltage. If the organic EL element is driven for a long period of time with the contaminants being left on the anode layer, the organic functional layer will be deteriorated, i.e. luminosity is degraded, due to a chemical reaction between the contaminants on the electrode and the organic functional layer material; however, it is possible to prevent such degradation in luminosity by the above-described organic EL element manufacturing method.

In addition, as a modification example, dry etching processing such as plasma etching may be performed in the etching processing, and dry ashing processing may be performed after the etching processing with the decompressed state being maintained. As described above, since the anode layer is not exposed to the air by maintaining the decompressed state after the etching processing, it is possible to prevent contamination by the contaminants such as organic substances and moisture in the air.

Next, one example of an organic EL element manufacturing apparatus of this invention will be described.

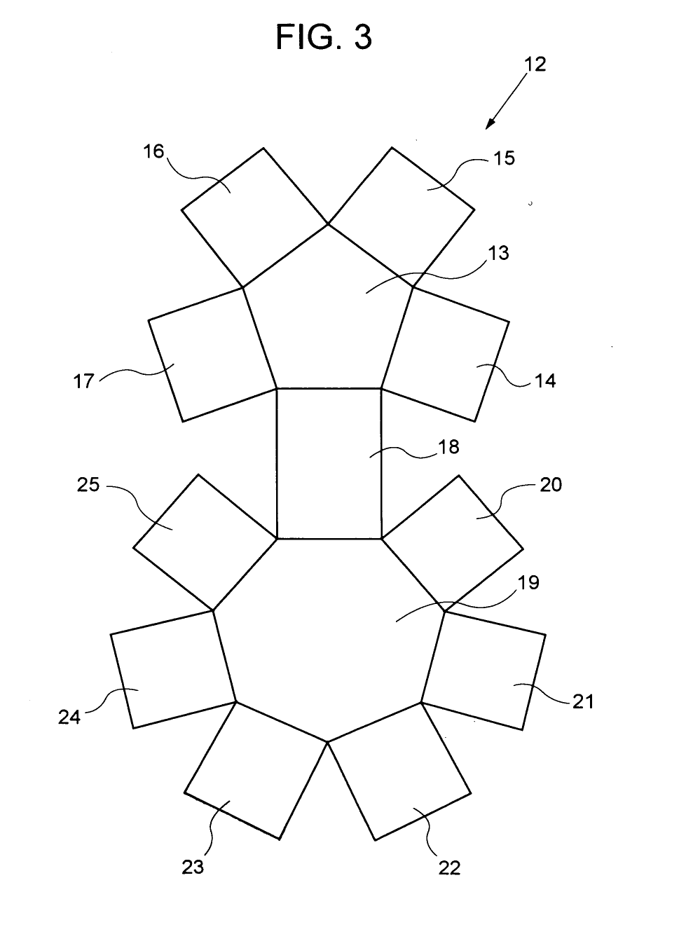

As shown in FIG. 3, an organic EL element manufacturing device 12 has a first conveyance chamber 13 which is provided with a first substrate conveying robot (not shown). The first conveyance chamber 13 is also provided with a decompression unit (not shown), and the decompression unit maintains a decompressed state of the first conveyance chamber.

A connection is provided between the first conveyance chamber 13 and a load chamber 14 used for introducing a substrate, on which an anode layer with a predetermined etching pattern is formed from the outside of the organic EL element manufacturing apparatus 12 into the first conveyance chamber 13. The load chamber 14 is provided with a decompression unit (not shown). After the substrate is introduced into the load chamber 14 from the outside of the organic EL element manufacturing apparatus 12, the air of the load chamber 14 is discharged by the use of the decompression unit. After the load chamber 14 is brought into the decompressed state, the first substrate conveying robot introduces the substrate into the first conveyance chamber 13.

The substrate introduced into the first conveyance chamber 13 is inserted into an ashing chamber 15 connected to the first conveyance chamber 13 by the first substrate conveying robot. The ashing chamber 15 is provided with a dry ashing device (not shown) and a decompression unit. As the dry ashing device, a plasma ashing device or an ozone ashing device may be used. The substrate is subjected to ashing processing by the ashing device under a reduced pressure, so that the resist on the anode layer is removed. The substrate from which the resist has been removed is then returned to the first conveyance chamber 13 by the first substrate conveying robot.

The substrate subjected to the ashing processing is then introduced into a surface treatment chamber 16 connected to the first conveyance chamber 13. The surface treatment chamber 16 is provided with at least one surface treatment device selected from a heat treatment device (not shown), a UV/ozone treatment device (not shown), an excimer treatment device (not shown), and a plasma treatment device (not shown) as well as a decompression unit (not shown). In the surface treatment chamber 16 maintained under a reduced pressure by the decompression unit, contaminants such as a resist residue deposited on a surface of the anode layer which performed the ashing processing are removed by the use of the surface treatment device. Also, a modification of the anode layer, such as an oxidation of the surface of the anode layer, is performed. By the oxidation, an ionization potential of the anode layer is increased.

The surface treatment chamber 16 may be provided with a plurality of surface treatment devices. For instance, the surface treatment chamber 16 may be provided with the excimer treatment device and the plasma treatment device. Particularly, it is preferable to combine a chemical cleaning device, i.e. the heat treatment device, the UV/ozone treatment device, or the excimer treatment device, with the plasma treatment device which is a physical cleaning device. With the above combination of devices, substances which are chemically decomposed are removed by the chemical cleaning device and substances which are not removed chemically are removed by the physical cleaning device, there by more efficiently removing the contaminants from the surface of the anode layer. The number of surface treatment chambers is not limited to one, and the organic EL element manufacturing apparatus may have a plurality of surface treatment chambers.

The substrate subjected to the surface treatment is conveyed from the surface treatment chamber 16 to a first organic functional layer formation chamber 17 connected to the first conveyance chamber 13 by the use of the first substrate conveying robot. The first organic functional layer formation chamber 17 is provided with a film formation device (not shown) employing a film formation method such as vapor deposition and a decompression unit (not shown), and the film formation device forms a hole injection layer on the anode layer under a reduced pressure.

The substrate provided with the hole injection layer is introduced into a stand-by chamber 18 connected to the first conveyance chamber 13. The stand-by chamber 18 is connected to a second conveyance chamber 19 provided with a second substrate conveying robot (not shown) and serves as a transfer section for delivering the substrate from the first conveyance chamber 13 to the second conveyance chamber 19. Therefore, the stand-by chamber is a part of the conveyance chamber to which the substrate is conveyed. The stand-by chamber 18 is provided with a decompression unit (not shown) and maintained in a decompressed state.

The second conveyance chamber 19 is provided with a decompression unit (not shown) and maintained in a decompressed state by the use of the decompression unit. The substrate introduced into the stand-by chamber 18 is inserted into the second conveyance chamber 19 by the second substrate conveying robot and then conveyed to a second organic functional layer formation chamber 20 connected to the second conveyance chamber 19. The second organic functional layer formation chamber 20 is provided with a film formation device (not shown) employing a film formation method such as vapor deposition and a decompression unit (not shown), and the film formation device forms a hole transport layer on the hole injection layer under a reduced pressure.

The second substrate conveying robot conveys the substrate on which the hole transport layer has been formed from the second organic functional layer formation chamber 20 to the second conveyance chamber 19 and then introduces into a third organic functional layer formation chamber 21 connected to the second conveyance chamber 19. The third organic functional layer formation chamber 21 is provided with a film formation device (not shown) employing a film formation method such as vapor deposition and a decompression unit (not shown), and the film formation device forms a light emission layer on the hole transport layer under a reduced pressure.

After the formation of the light emission layer, the second substrate conveying robot conveys the substrate from the third organic functional layer formation chamber 21 to the second conveyance chamber 19 and then introduces into a fourth organic functional layer formation chamber 22 connected to the second conveyance chamber 19. The fourth organic functional layer formation chamber 22 is provided with a film formation device (not shown) employing a film formation method such as vapor deposition and a decompression unit (not shown), and the film formation device forms an electron injection transport layer on the light emission layer under a reduced pressure. The stack formed of the hole injection layer, the hole transport layer, the light emission layer, and the electron injection transport layer serves as an organic functional layer.

After the formation of the electron injection transport layer, the second substrate conveying robot conveys the substrate from the fourth organic functional layer formation chamber 22 to the second conveyance chamber 19 and then introduces into a cathode layer formation chamber 23 connected to the second conveyance chamber 19. The cathode layer formation chamber 23 is provided with a film formation device (not shown) employing a film formation method such as vapor deposition and a decompression unit (not shown), and the film formation device forms a cathode layer made of a low resistance material such as aluminum on the organic functional layer under a reduced pressure. Upon completion of the cathode layer formation, an organic EL element formed of the anode layer, the organic functional layer, and the cathode layer is obtained.

The substrate on which the cathode layer has been formed is conveyed from the cathode layer formation chamber 23 to a sealing chamber 24 connected to the second conveyance chamber 19 by the second substrate conveying robot. The sealing chamber 24 is provided with a film formation device (notshown) employing a film formation method such as plasma CVD and a decompression unit (not shown), and the film formation device forms a sealing layer which is made of an inorganic material such as silicon nitride and seals the organic EL element, under a reduced pressure.

The substrate on which the sealing layer has been formed is conveyed to an unload chamber 25 via the second conveyance chamber 19. The unload chamber 25 is a site at which the substrate with the organic EL element sealed with the sealing layer is taken out of the organic EL element manufacturing apparatus 12. The unload chamber 25 is provided with a pressurizing unit (not shown) such as a valve for introducing the air for returning the decompressed state to the atmospheric pressure.

As described above, since the anode layer surface is not exposed to the air before the formation of the organic functional layer with the use of the organic EL element manufacturing apparatus, the organic EL element manufacturing apparatus is capable of maintaining the anode layer surface clean and obtaining an organic EL element which emits light with a low voltage and has high luminosity and a long life.

Further, since the resist is perfectly removed by the ashing and the surface treatment, it is possible to keep the anode layer surface clean.

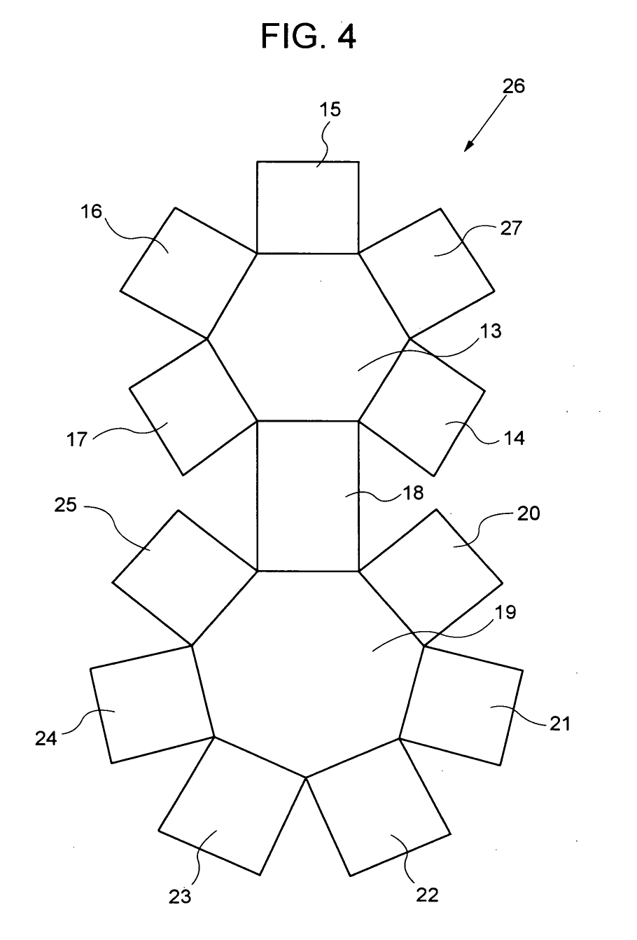

As a modification example, the organic EL element manufacturing apparatus may be provided with an etching chamber for performing etching processing on the anode layer. For instance, as shown in FIG. 4, an organic EL element manufacturing apparatus 26 is provided with an etching chamber 27 which is disposed between the load chamber 14 and the ashing chamber 15 and connected to the first conveyance chamber with the other constituents being the same as those of the above-described organic EL element manufacturing apparatus 12 shown in FIG. 3. The etching chamber 27 is provided with a dry etching device (not shown) and a decompression unit (not shown). As the dry etching device, a plasma etching device using an etching gas such as a halogen gas or a reactive ion etching device using a mixture gas of a halogenated hydrogen gas and an inert gas may be used.

In the organic EL element manufacturing apparatus 26 with the above constitution, a substrate on which a resist with a predetermined pattern has been disposed is introduced in to the load chamber 14. The substrate in the load chamber 14 is conveyed to the first conveyance chamber 13 by the first substrate conveyance robot and then introduced into the etching chamber 27. The anode layer of the substrate introduced into the etching chamber 27 is subjected to dry etching processing under a reduced pressure using the resist as a mask.

After the etching processing, the first substrate conveying robot conveys the substrate to the ashing chamber 15 via the first conveyance chamber 13. In the organic EL element manufacturing apparatus 26, the process steps taken in the course of from the ashing chamber 15 to the unload chamber 25 are substantially the same as those taken in the course of from the ashing chamber 15 to the unload chamber 25 of the above-described organic EL element manufacturing apparatus 12 shown in FIG. 3.

According to the above-described organic EL element manufacturing apparatus, since the anode layer is not exposed to the air after the etching processing, it is possible to prevent contaminants in the air from depositing on the surface of the anode layer, thereby facilitating cleaning after the etching processing. Therefore, it is possible to form an organic EL element in which no contaminant exists on the surface of the anode layer.

The organic EL element manufacturing apparatus in the above example has four organic functional layer formation chambers because the organic functional layer is the four layer structure, but the number of organic functional layer formation chambers is not limited thereto. For instance, in the case where the organic functional layer is a three layer structure formed of a hole injection transport layer, a light emission layer, and an electron injection transport layer, the organic EL element manufacturing apparatus may have three organic functional layer formation chambers.

According to the organic electroluminescent element manufacturing method of this invention, comprising: an anode layer formation process including an anode film formation step of forming an anode layer on a substrate, a step of disposing a resist on the anode layer, an etching step of performing etching processing on the anode layer by using the resist as a mask, a resist removal step of removing the resist by dry ashing processing after the etching step, and a surface treatment step of performing a surface treatment on the anode layer after the resist removal step; an organic functional layer formation process for forming an organic functional layer having at least a light emission layer on the anode layer; a cathode layer formation process for forming a cathode layer on the organic functional layer; and a sealing process for sealing an organic electroluminescent element formed of the anode layer, the organic functional layer, and the cathode layer with a sealing member, wherein the anode layer is not exposed to the air after the resist removal step, because an anode layer pattern is formed by the etching processing using the resist, it is possible to form the anode layer pattern in minute details as compared with the case of using a metal mask, and, because the organic functional layer is formed in a state where contamination of the anode layer by the air is prevented and the resist is perfectly removed, it is possible to prevent a reduction in hole injection efficiency from the organic functional layer to the organic functional layer otherwise caused by the contamination, thereby obtaining an organic EL element achieving high luminosity with a low voltage.

According to the organic EL element manufacturing apparatus of this invention, comprising: a processing unit including a load chamber for introducing a structural body having a substrate, an anode layer provided on the substrate, and a resist disposed on the anode layer, an ashing chamber for removing the resist by dry ashing, a surface treatment chamber for performing a surface treatment on a surface of the anode layer from which the resist has been removed, an organic functional layer formation chamber for forming an organic functional layer on the anode layer on which the surface treatment has been performed, a cathode layer formation chamber for forming a cathode layer on the organic functional layer, and a sealing chamber for sealing an organic electroluminescent element formed of the anode layer, the organic functional layer, and the cathode layer with a sealing member; and a conveyance chamber which is provided with a connection to the processing unit and a unit for conveying the substrate, wherein the conveyance chamber includes a decompression unit, because it is possible to remove the resist perfectly from the anode layer and to prevent contamination of the anode layer by the air, it is possible to prevent deterioration in the organic functional layer due to a reaction between contaminants deposited on the anode layer and the organic functional layer, thereby enabling a formation of a long life organic EL element.

This application is based on a Japanese patent application No. 2003-393685 which is hereby incorporated by reference.

1. An organic electroluminescent element manufacturing method comprising:
an anode layer formation process including an anode film formation step of forming an anode layer on a substrate, a step of disposing a resist on the anode layer, an etching step of performing etching processing on the anode layer by using the resist as a mask, a resist removal step of removing the resist by dry ashing processing after the etching step, and a surface treatment step of performing a surface treatment on the anode layer after the resist removal step;
an organic functional layer formation process for forming an organic functional layer having at least a light emission layer on the anode layer after the anode layer formation process;
a cathode layer formation process for forming a cathode layer on the organic functional layer; and
a sealing process for sealing an organic electroluminescent element formed of the anode layer, the organic functional layer, and the cathode layer with a sealing member, wherein
the anode layer is not exposed to the air after the resist removal step.

2. The organic electroluminescent element manufacturing method according to claim 1, wherein wet etching processing is performed in the etching step.

3. The organic electroluminescent element manufacturing method according to claim 1, wherein dry etching processing is performed in the etching step.

4. The organic electroluminescent element manufacturing method according to claim 3, wherein the anode layer is not exposed to the air after the etching step.

5. The organic electroluminescent element manufacturing method according to claim 4, wherein the dry etching processing is plasma etching processing.

6. The organic electroluminescent element manufacturing method according to claim 4, wherein the dry etching processing is reactive ion etching processing.

7. The organic electroluminescent element manufacturing method according to claim 1, wherein the dry ashing processing is plasma ashing processing.

8. The organic electroluminescent element manufacturing method according to claim 1, wherein the dry ashing processing is ozone ashing processing.

9. The organic electroluminescent element manufacturing method according to claim 1, wherein at least one of a heat treatment, a UV/ozone treatment, an excimer treatment, and a plasma treatment is performed in the surface treatment step.

10. An organic EL element manufacturing apparatus comprising:
a processing unit including
a load chamber for introducing a structural body having a substrate, an anode layer provided on the substrate, and a resist disposed on the anode layer,
an ashing chamber for removing the resist by dry ashing,
a surface treatment chamber for performing a surface treatment on a surface of the anode layer from which the resist has been removed,
an organic functional layer formation chamber for forming an organic functional layer on the anode layer on which the surface treatment has been performed,
a cathode layer formation chamber for forming a cathode layer on the organic functional layer, and
a sealing chamber for sealing an organic electroluminescent element formed of the anode layer, the organic functional layer, and the cathode layer with a sealing member; and
a conveyance chamber which is provided with a connection to the processing unit and a unit for conveying the substrate, wherein
the conveyance chamber includes a decompression unit.

11. The manufacturing apparatus according to claim 10, wherein the processing unit has an etching chamber for performing dry etching processing on the anode layer with the resist being used as a mask.

12. The manufacturing apparatus according to claim 11, wherein the etching chamber is provided with a plasma etching processing unit.

13. The manufacturing apparatus according to claim 11, wherein the etching chamber is provided with a reactive ion etching processing unit.

14. The manufacturing apparatus according to claim 10, wherein the ashing chamber is provided with a plasma ashing processing unit.

15. The manufacturing apparatus according to claim 10, wherein the ashing chamber is provided with an ozone ashing processing unit.

16. The manufacturing apparatus according to claim 10, wherein the surface treatment chamber is provided with at least one of a heat treatment unit, a UV/ozone treatment unit, an excimer treatment unit, and a plasma treatment unit.
